(19) United States
(12) Patent Application Publication
(10) Pub. No.: US 2013/0148311 A1
(43) Pub. Date: Jun. 13, 2013

(54) DOUBLE-LAYER PCB OF LOW POWER WIRELESS SENSING SYSTEM AND MANUFACTURING METHOD

(71) Applicants: Chia-Chi CHANG, Taoyuan County (TW); Jang Ping Sheu, Hsinchu City (TW)

(72) Inventors: Chia-Chi CHANG, Taoyuan County (TW); Jang Ping Sheu, Hsinchu City (TW)

(21) Appl. No.: 13/523,558

(22) Filed: Jun. 14, 2012

(30) Foreign Application Priority Data
Dec. 9, 2011 (TW) 100145550

(51) Int. Cl. H05K 7/02; H05K 3/30; H05K 3/36; H04B 7/00

(52) U.S. Cl. 361/729; 29/832; 29/830

(57) ABSTRACT

The invention discloses a double-layer PCB of a low power wireless sensing system and a manufacturing method thereof. The low power wireless sensing system includes a first layer and a second layer. The first layer comprises a wireless communication module, a power amplifying module, a USB module, a balun module, an antenna module, a low-frequency oscillator and a high-frequency oscillator. According to the double-layer PCB of the low power wireless sensing system and the manufacturing method thereof, a circuit layout can be performed on the double-layer PCB to reduce volume of the PCB.

This application claims priority of No. 100145550 filed in Taiwan R.O.C. on Dec. 9, 2011 under 35 USC 119, the entire content of which is hereby incorporated by reference.

### BACKGROUND OF THE INVENTION

1. Field of the Invention

The invention relates to a double-layer printed circuit board (PCB) and a manufacturing method thereof, and more particularly to a double-layer PCB of a low power wireless sensing system and a manufacturing method thereof.

2. Related Art

A memory of an existing wireless sensing system is fixed in the system and cannot be replaced, and firmware data of the memory cannot be easily updated.

Furthermore, the current wireless sensing system cannot transmit the data through the Ethernet, thereby causing the convenience in use. Also, the circuit layout of the wireless sensing system needs to be performed through a four-layer PCB. Because the four-layer PCB has the larger volume, the manufacturing cost and the user's loading are increased.

### SUMMARY OF THE INVENTION

An object of the invention is to provide a double-layer PCB of a low power wireless sensing system and a manufacturing method thereof, so that the low power wireless sensing system has a detabhable external memory module and a universal serial bus (USB) module.

Another object of the invention is to provide a double-layer PCB of a low power wireless sensing system and a manufacturing method thereof capable of decreasing the cost.

Still another object of the invention is to provide a double-layer PCB of a low power wireless sensing system and a manufacturing method thereof capable of reducing the volume of the PCB.

Yet still another object of the invention is to provide a double-layer PCB of a low power wireless sensing system and a manufacturing method thereof so that the circuit layout can be performed using the double-layer PCB.

One embodiment of the invention provides a double-layer PCB of a low power wireless sensing system including a first layer, a second layer and a dielectric layer. The first layer comprises a wireless communication module, a power amplifying module, a universal serial bus (USB) module, a balun module, an antenna module, a low-frequency oscillator and a high-frequency oscillator. The wireless communication module is disposed in a central region of the first layer. The power amplifying module is disposed on a right side of the wireless communication module. The USB module is disposed in a left-side region of the wireless communication module. One of sides of the balun module is disposed between the wireless communication module and the power amplifying module. The antenna module is disposed in a rightmost-side region of the first layer, and the antenna module is coupled to the other side of the balun module. The low-frequency oscillator and the high-frequency oscillator are disposed in neighboring right-side regions of the wireless communication module along a first direction. The second layer comprises a flash memory module and a detabhable external memory module. A user transmits firmware data to the flash memory module or the detabhable external memory module through a radio frequency signal, or stores the firmware data to the detabhable external memory module in advance. The dielectric layer is disposed between the first layer and the second layer and insulates the first layer from the second layer. Surface of the first layer and the second layer are formed with a plurality of vias coupled to traces of the first layer and the second layer.

Another embodiment of the invention provides a method of manufacturing a double-layer printed circuit board (PCB) of a low power wireless sensing system. The method comprises the steps of: disposing a wireless communication module, a power amplifying module and a universal serial bus (USB) module on a surface of a first layer of the double-layer PCB, wherein the wireless communication module is disposed in a central region of the first layer; disposing a balun module on two sides of the power amplifying module along a horizontal direction; disposing a low-frequency oscillator and a high-frequency oscillator in neighboring right-side regions of the wireless communication module along a first direction, wherein the low-frequency oscillator is located on a top side of the balun module, and the high-frequency oscillator is located on a bottom side of the balun module; disposing a decoupling capacitor unit in a neighboring region of a power module; and disposing an analog-to-digital converter circuit trace, a first clock circuit trace and a second clock circuit trace in neighboring regions of the wireless communication module. The wireless communication module is coupled to the power module through a first circuit trace, and the first circuit trace has a first diameter. The low-frequency oscillator and the high-frequency oscillator are coupled to the wireless communication module through the first clock circuit trace and the second clock circuit trace, and the first clock circuit trace and the second clock circuit trace have a second diameter and a third diameter, respectively. The analog-to-digital converter circuit trace has a fourth diameter.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a schematic illustration showing a double-layer PCB used in a low power wireless sensing system of the invention.

FIG. 2A is a schematic illustration showing the circuit layout of a first layer of the low power wireless sensing system of the invention.

FIG. 2B is a schematic illustration showing the circuit layout of the first layer of the low power wireless sensing system of the invention.

FIG. 2C is a schematic illustration showing the circuit layout of the first layer of the low power wireless sensing system of the invention.

FIG. 2D is a schematic illustration showing the circuit layout of the first layer of the low power wireless sensing system of the invention.

FIG. 2E is a schematic illustration showing the circuit layout of a second layer of the low power wireless sensing system of the invention.

FIG. 3 is a flow chart showing a manufacturing method of the low power wireless sensing system of the invention.

### DETAILED DESCRIPTION OF THE INVENTION

The present invention will be apparent from the following detailed description, which proceeds with reference to the accompanying drawings, wherein the same references relate to the same elements.

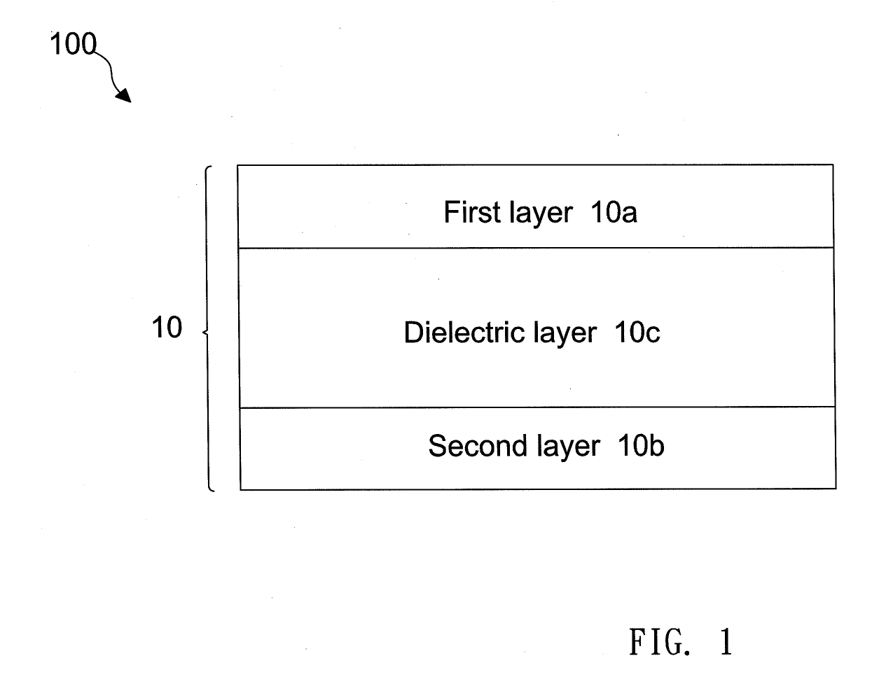

FIG. 1 is a schematic illustration showing a double-layer printed circuit board (PCB) 10 used in a low power wireless sensing system 100 of the invention. Referring to FIG. 1, the circuit layout of the low power wireless sensing system 100 according to an embodiment of the invention may be performed on the double-layer PCB 10 using the standard FR-2 process technology. The double-layer PCB 10 includes a first layer 10a, a second layer 10b and a dielectric layer 10c. In one embodiment, each thickness of the first layer 10a and the second layer 10b may be equal to 35 microns (μm), and the thickness of the dielectric layer 10c may be equal to 0.34 mm.

The dielectric layer 10c is disposed between the first layer 10a and the second layer 10b, holds the insulating property between the layers and prevents the first layer 10a and the second layer 10b from interfering with each other. In addition, the low power wireless sensing system 100 according to one embodiment of the invention can utilize the Zig Bee wireless network protocol to perform the data transmission.

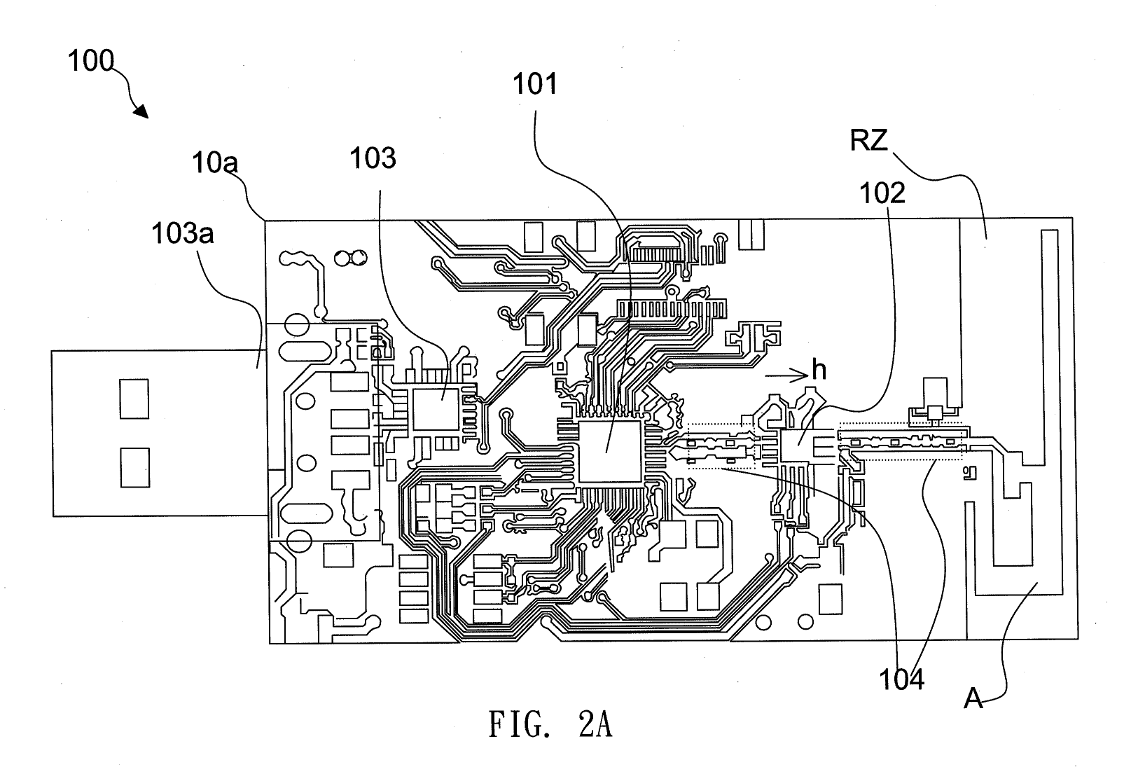

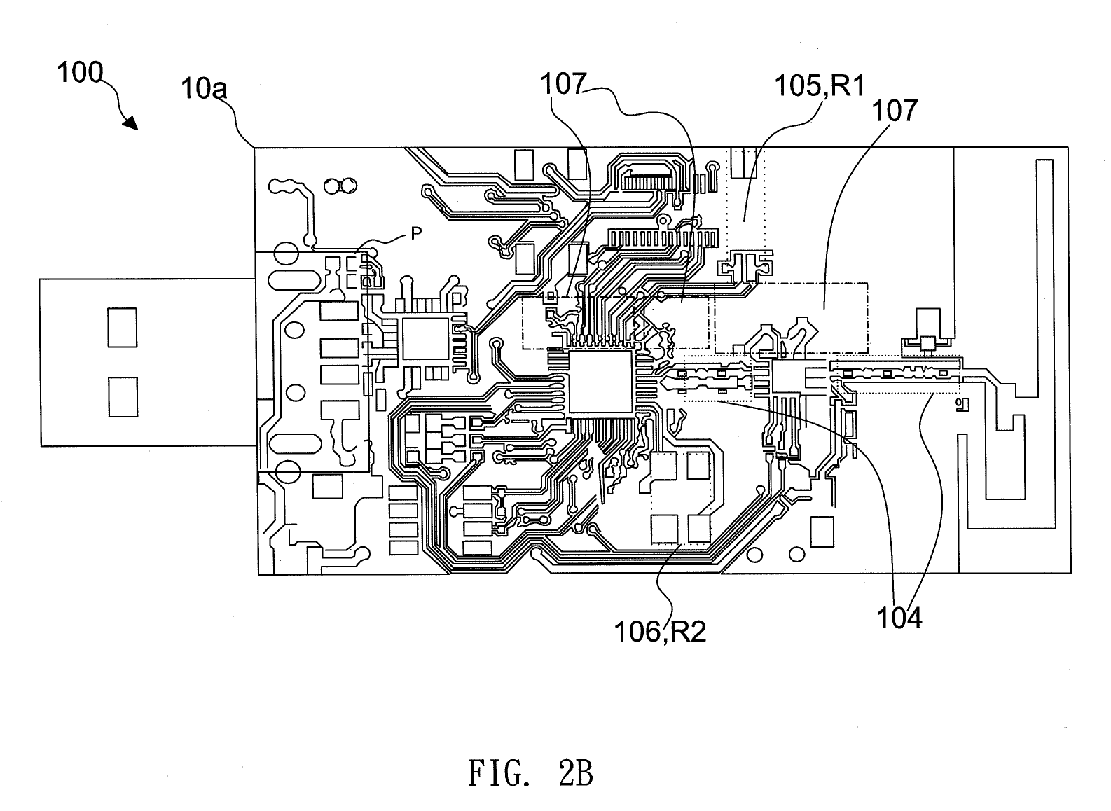

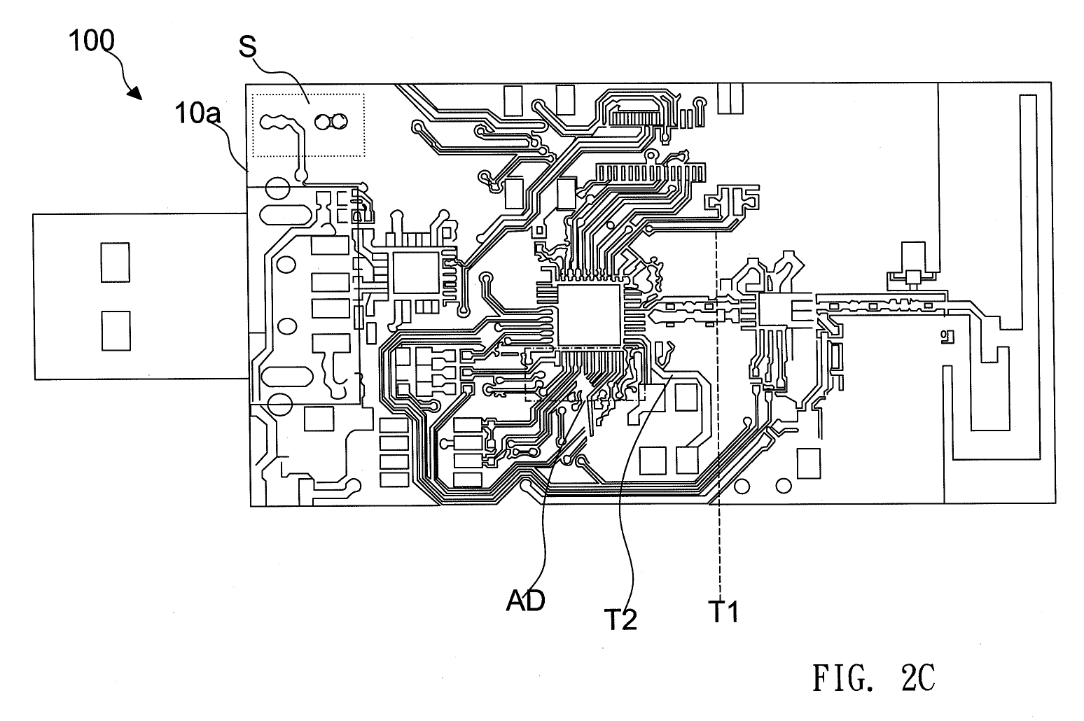

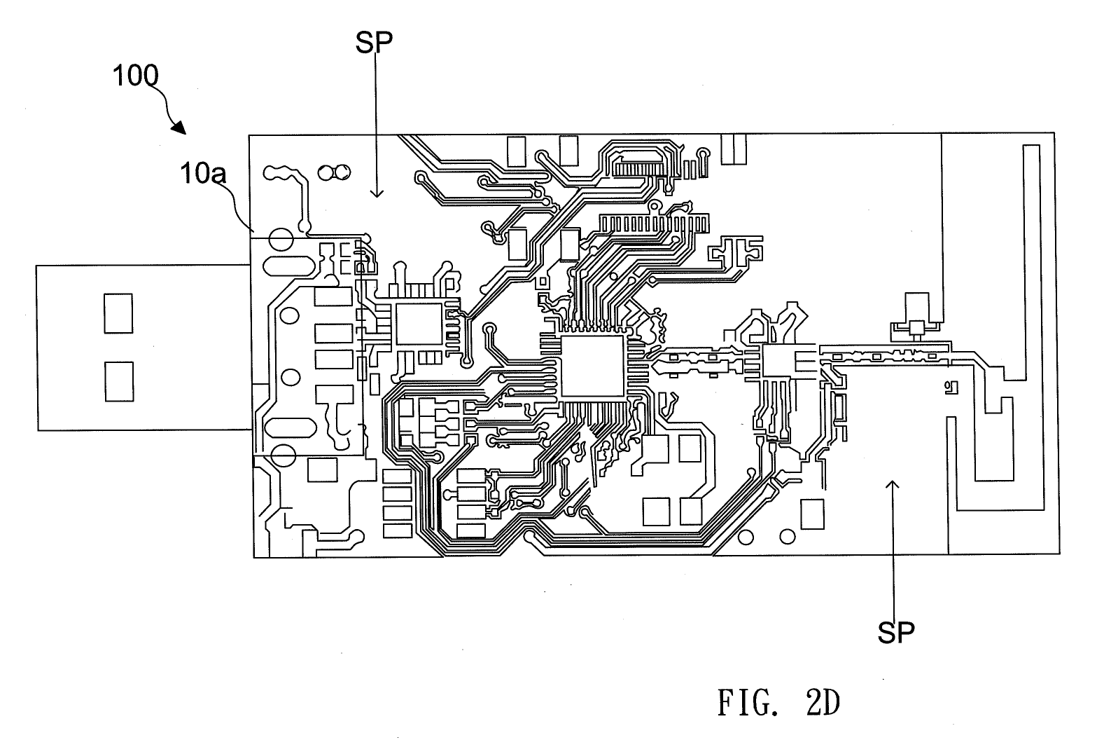

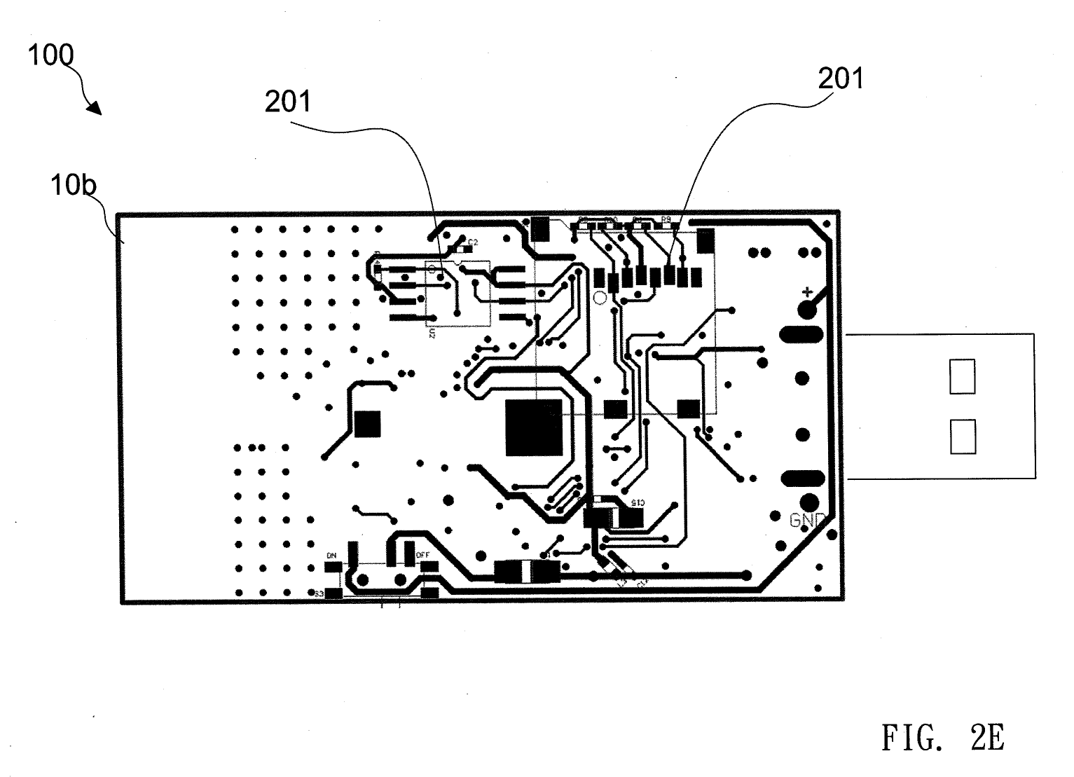

FIG. 2A is a schematic illustration showing the circuit layout of the first layer 10a of the low power wireless sensing system 100 of the invention. Please refer to FIGS. 1 and 2A, the double-layer PCB 10 of the low power wireless sensing system 100 in one embodiment has the length of 57 mm and the width of 30 mm. First, a wireless communication module 101, a power amplifying module 102, a universal serial bus (hereinafter referred to as USB) module 103 and a balun module 104 are disposed on a surface of the first layer 10a of the double-layer PCB 10. Please note that the wireless communication module 101 in this embodiment may be implemented by the CC2530 chipset manufactured by Texas Instruments.

The wireless communication module 101 is disposed in a central region of the first layer 10a. In one embodiment, the CC2530 chipset is disposed at a center position on the surface of the first layer 10a of the PCB 10. The power amplifying module 102 is disposed on the right side of the wireless communication module 101. In this embodiment, the power amplifying module 102 is implemented by the CC2591 chipset manufactured by Texas Instruments. The USB module 103 is disposed in a left-side region of the wireless communication module 101, neighbors a USB connector 103a, and is coupled to the USB connector 103a.

The balun module 104 is disposed on two sides of the power amplifying module 102 along a horizontal direction h. In other words, one of the sides of the balun module 104 is disposed between the wireless communication module 101 and the power amplifying module 102 and disposed on a line connecting the wireless communication module 101 to the power amplifying module 102. The power amplifying module 102′ increases the transmitted power of the low power wireless sensing system 100.

Please note that the manufacturing method of the invention additionally disposes an antenna module A in a rightmost-side region RZ of the first layer 10a in advance, wherein the antenna module A is coupled to the other side of the balun module 104.

FIG. 2B is a schematic illustration showing the circuit layout of the first layer of the low power wireless sensing system of the invention. As shown in FIG. 2B, a low-frequency oscillator 105 and a high-frequency oscillator 106 are disposed in neighboring right-side regions R1 and R2 of the wireless communication module 101 along a first direction D1. The low-frequency oscillator 105 is located on a top side of the balun module 104, the high-frequency oscillator 106 is located on a bottom side of the balun module 104. In other words, the right-side region R1 is located on the top side of the balun module 104, and the right-side region R2 is located on the bottom side of the balun module 104.

Please note that diameters of internal circuit traces of the low-frequency oscillator 105 and the high-frequency oscillator 106 in this embodiment may be equal to 12 mils. The wireless communication module 101 is disposed in a neighboring region of the power module P, the circuit trace distance from the wireless communication module 101 to the power module P is preferably shorter. Also, the wireless communication module 101 is coupled to the power module P through a first circuit trace having a first diameter. In one embodiment, the first diameter may be equal to 14 mils.

In addition, three decoupling capacitor units 107 are disposed in the neighboring regions of the power module P and located in a top side region neighboring the wireless communication module 101.

FIG. 2C is a schematic illustration showing the circuit layout of the first layer of the low power wireless sensing system of the invention. At last, an analog-to-digital converter circuit trace AD, a first clock circuit trace T1 and a second clock circuit trace T2 are disposed in the neighboring regions of the wireless communication module 101. The low-frequency oscillator 105 is coupled to the wireless communication module 101 through the first clock circuit trace T1, the high-frequency oscillator 106 is coupled to the wireless communication module 101 through the second clock circuit trace T2, and the analog-to-digital converter circuit trace AD is coupled to a sensing circuit S and the wireless communication module 101.

In the main layout method according to one embodiment, the first clock circuit trace T1 and the second clock circuit trace T2 are preferably straight lines. In addition, a diameter of each of the analog-to-digital converter circuit trace AD, the first clock circuit trace T1 and the second clock circuit trace T2 in one embodiment may be equal to 8 mils. In addition, the layout of the analog-to-digital converter circuit trace AD, the first clock circuit trace T1 and the second clock circuit trace T2 may be completely grounded to isolate the interference of noise.

Please refer to FIG. 2D. FIG. 2D is a schematic illustration showing the circuit layout of the first layer of the low power wireless sensing system of the invention. In one embodiment, bottom portions of the wireless communication module 101, the power amplifying module 102 and the USB module 103 are grounded using bare copper so that the noise can be effectively isolated and the heat dissipating function of each module can be enhanced. In addition, the non-layout region SP is treated and grounded by arranging the copper so that the interference of noise can be decreased, and its entire surface are treated by the lead-free tin spraying treatment and the hole filling treatment.

Please refer to FIG. 2E. FIG. 2E is a schematic illustration showing the circuit layout of a second layer of the low power wireless sensing system of the invention. In the low power wireless sensing system 100 according to one embodiment of the invention, a flash memory module 201 and a detabhable external memory module 202 are disposed on the surface of the second layer 10b. So, the low power wireless sensing system 100 of the invention can perform the remote firmware updating. In one embodiment, the user can transmit the firmware F1 to the flash memory module 201 or the detabhable external memory module 202 through a radio frequency signal RF, or store the firmware to the detabhable external memory module 202 in advance. When the user needs to update the original firmware of the low power wireless sensing system 100, the wireless communication module 101 can generate the corresponding updating according to the firmware.

Please note that the surfaces of the first layer 10a and the second layer 10b have a plurality of vias. The vias can conduct the traces of the first layer 10a to the traces of the second layer 10b. For the sake of coinciseness in the drawings, the vias are only depicted in FIG. 2E.

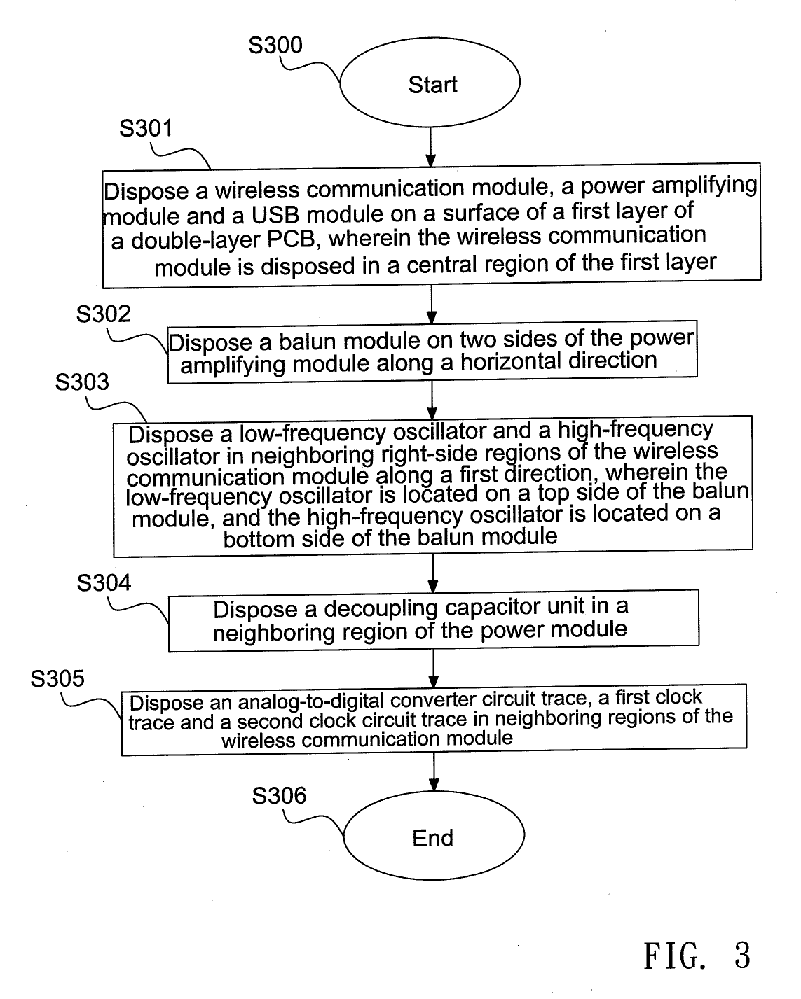

FIG. 3 is a flow chart showing a manufacturing method of the low power wireless sensing system of the invention. Referring to FIG. 3, the manufacturing method includes the following steps.

In step S300, the method starts.

In step S301, the wireless communication module, the power amplifying module and the USB module are disposed on the surface of the first layer of the double-layer PCB, wherein the wireless communication module is disposed in the central region of the first layer.

In step S302, the balun module is disposed on two sides of the power amplifying module along a horizontal direction.

In step S303, the low-frequency oscillator and the high-frequency oscillator are disposed in neighboring right-side regions of the wireless communication module along the first direction, wherein the low-frequency oscillator is located on the top side of the balun module, and the high-frequency oscillator is located on the bottom side of the balun module.

In step S304, the decoupling capacitor unit is disposed in the neighboring region of the power module.

In step S305, the analog-to-digital converter circuit trace, the first clock circuit trace and the second clock circuit trace are disposed in the neighboring regions of the wireless communication module.

In step S306, the method ends.

In summary, the manufacturing method of the double-layer PCB of the low power wireless sensing system of the invention can provide a wireless sensing system having the long-distance transmission capability, and the user can perform the data transmission and provide the power through a USB port, thereby facilitating the connection to a desktop computer or a notebook computer.

While the present invention has been described by way of examples and in terms of preferred embodiments, it is to be understood that the present invention is not limited thereto. To the contrary, it is intended to cover various modifications. Therefore, the scope of the appended claims should be accorded the broadest interpretation so as to encompass all such modifications.

What is claimed is:

1. A double-layer printed circuit board (PCB) of a low power wireless sensing system, comprising:
a first layer comprising a wireless communication module, a power amplifying module, a universal serial bus (USB) module, a balun module, an antenna module, a low-frequency oscillator and a high-frequency oscillator, wherein:
the wireless communication module is disposed in a central region of the first layer;
the power amplifying module is disposed on a right side of the wireless communication module;
the USB module is disposed in a left-side region of the wireless communication module;
one of sides of the balun module is disposed between the wireless communication module and the power amplifying module;
the antenna module is disposed in a rightmost-side region of the first layer, and the antenna module is coupled to the other side of the balun module; and
the low-frequency oscillator and the high-frequency oscillator are disposed in neighboring right-side regions of the wireless communication module along a first direction;
a second layer, comprising a flash memory module and a detabhable external memory module, wherein:
a user transmits firmware data to the flash memory module or the detabhable external memory module through a radio frequency signal, or stores the firmware data to the detabhable external memory module in advance; and
a dielectric layer, which is disposed between the first layer and the second layer and insulates the first layer from the second layer, wherein surfaces of the first layer and the second layer are formed with a plurality of vias coupled to traces of the first layer and the second layer.

2. The double-layer PCB according to claim 1, wherein when the user needs to update original firmware of the low power wireless sensing system, the wireless communication module performs updating according to the firmware data.

3. A method of manufacturing a double-layer printed circuit board (PCB) of a low power wireless sensing system, the method comprising the steps of:
disposing a wireless communication module, a power amplifying module and a universal serial bus (USB) module on a surface of a first layer of the double-layer PCB, wherein the wireless communication module is disposed in a central region of the first layer;
disposing a balun module on two sides of the power amplifying module along a horizontal direction;
disposing a low-frequency oscillator and a high-frequency oscillator in neighboring right-side regions of the wireless communication module along a first direction, wherein the low-frequency oscillator is located on a top side of the balun module, and the high-frequency oscillator is located on a bottom side of the balun module;
disposing a decoupling capacitor unit in a neighboring region of a power module; and
disposing an analog-to-digital converter circuit trace, a first clock circuit trace and a second clock circuit trace in neighboring regions of the wireless communication module, wherein:
the wireless communication module is coupled to the power module through a first circuit trace, and the first circuit trace has a first diameter;
the low-frequency oscillator and the high-frequency oscillator are coupled to the wireless communication module through the first clock circuit trace and the second clock circuit trace, and the first clock circuit trace and the second clock circuit trace have a second diameter and a third diameter, respectively; and
the analog-to-digital converter circuit trace has a fourth diameter.

4. The method according to claim 3, wherein an antenna module is disposed in a rightmost-side region of the first layer in advance, and the antenna module is coupled to one side of the balun module.

5. The method according to claim 4, wherein the wireless communication module is disposed in the neighboring region of the power module, and the first diameter is equal to 14 mils.

6. The method according to claim 4, wherein diameters of internal circuit traces of the low-frequency oscillator and the high-frequency oscillator are equal to 12 mils.

7. The method according to claim 4, wherein the analog-to-digital converter circuit trace is coupled to a sensing circuit and the wireless communication module, and the second diameter, the third diameter and a diameter of the analog-to-digital converter circuit trace are equal to 8 mils.

8. The method according to claim 4, wherein bottom portions of the wireless communication module, the power amplifying module and the USB module are grounded using bare copper.

9. The method according to claim 4, wherein a dielectric layer is disposed between the first layer and the second layer and prevents the first layer and a second layer from interfering with each other.

10. The method according to claim 4, wherein a flash memory module and a detabhable external memory module are disposed on a surface of the second layer.

11. The method according to claim 4, wherein a circuit layout method of the low power wireless sensing system utilizes standard FR-2 process technology.

12. The method according to claim 11, wherein a dielectric layer is disposed between the first layer and the second layer, and the dielectric layer prevents the first layer and the second layer from interfering with each other.
